(19) United States
(12) Patent Application Publication
(10) Pub. No.: US 2025/0294802 A1
(43) Pub. Date: Sep. 18, 2025

(54) SEMICONDUCTOR DEVICE AND METHOD FOR FORMING THE SAME

(71) Applicant: Hon Young Semiconductor Corporation, Hsinchu City (TW)

(72) Inventors: Iram SIDDIQUI, Hsinchu City (TW); Kuang-Hao CHIANG, Hsinchu City (TW); Yan-Ru CHEN, Hsinchu City (TW)

(21) Appl. No.: 18/661,722

(22) Filed: May 13, 2024

(30) Foreign Application Priority Data
Mar. 15, 2024 (TW) 113109803

(51) Int. Cl. H01L 29/78; H01L 29/66

(52) U.S. Cl. CPC H10D 30/668; H10D 30/0297

(57) ABSTRACT

A semiconductor device includes an epitaxial layer, a gate structure, a well, and a source electrode. The epitaxial layer has a first conductive type. The gate structure and the well are disposed in the epitaxial layer. The well has a second conductive type different from the first conductive type. The well extends from a sidewall of the gate structure to a bottom surface of the gate structure. The source electrode is disposed above the epitaxial layer and is electrically connected to the well.

### CROSS-REFERENCE TO RELATED APPLICATION

This application claims priority to Taiwan Application Serial Number 113109803, filed Mar. 15, 2024, which is herein incorporated by reference in its entirety.

### BACKGROUND

### Field of Disclosure

The present disclosure relates to a semiconductor device and a method for forming the same.

### Description of Related Art

Metal oxide semiconductor field effect transistors (MOSFET) are widely used in electronic devices due to their advantages such as fast switching speed, ideal high-frequency characteristics, high input impedance, and low driving power. Generally speaking, the on-state resistance of MOSFETs is an important parameter that affects their power consumption. MOSFETs with trench gate structures have higher channel density. Such characteristic can help reduce the on-state resistance and scale down the component size, therefore increasing the component density of the chip and reducing costs.

However, the gate structures of trench gate power MOSFETs may induce large electric field concentrations, which may reduce the breakdown voltage of the components and thus cause reliability problems.

Accordingly, how to provide a semiconductor device and a method for forming the semiconductor device to solve the aforementioned problems becomes an important issue to be solved by those in the industry.

### SUMMARY

An aspect of the disclosure is to provide a semiconductor device and a method for forming the semiconductor device that may efficiently solve the aforementioned problems.

According to some embodiments of the present disclosure, a semiconductor device includes an epitaxial layer, a gate structure, a well, and a source electrode. The epitaxial layer has a first conductive type. The gate structure and the well are disposed in the epitaxial layer. The well has a second conductive type that is different from the first conductive type. The well extends from a sidewall of the gate structure to a bottom surface of the gate structure. The source electrode is disposed above the epitaxial layer and is electrically connected to the well.

According to some other embodiments of the present disclosure, a method for forming a semiconductor device includes forming an epitaxial layer on a substrate. The epitaxial layer has a first conductive type. The method further includes performing a first implantation process to form a first portion of a well in the epitaxial layer. The first portion of the well has a second conductive type different from the first conductive type. The method further includes performing a second implantation process to form a second portion of the well in the epitaxial layer and adjacent to the first portion. The second portion of the well has the second conductive type. The method further includes performing a third implantation process to form a heavily doped region in the epitaxial layer and adjacent to the well. The heavily doped region has the second conductive type. The method further includes removing a portion of the epitaxial layer to form a trench. The trench exposes a top surface of the second portion of the well. The method further includes forming a gate structure in the trench.

Accordingly, in the semiconductor device and the method for forming the semiconductor device of some embodiments of the present disclosure, by increasing the depth of the well (i.e., the maximum depth of the lightly doped region) so that the well covers the corner points of the gate structure, the electric field accumulation around the corner points may be reduced. To be more specific, by performing two ion implantation processes, the first portion and the second portion of the well are formed. The first portion surrounds the sidewall of the gate structure, and the second portion extends to the bottom surface of the gate structure. As such, the junction between the sidewall and the bottom surface of the gate structure is covered by the first portion and the second portion of the well. Therefore, the breakdown voltage of the semiconductor device can be improved and its on-state resistance can be reduced.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial cross-sectional view of a semiconductor device according to some embodiments of the present disclosure;

FIG. 2 to FIG. 5 are partial cross-sectional views of intermediate stages of a method for forming a semiconductor device according to some embodiments of the present disclosure; and

FIG. 6 and FIG. 7 are partial cross-sectional views of a semiconductor device according to some other embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

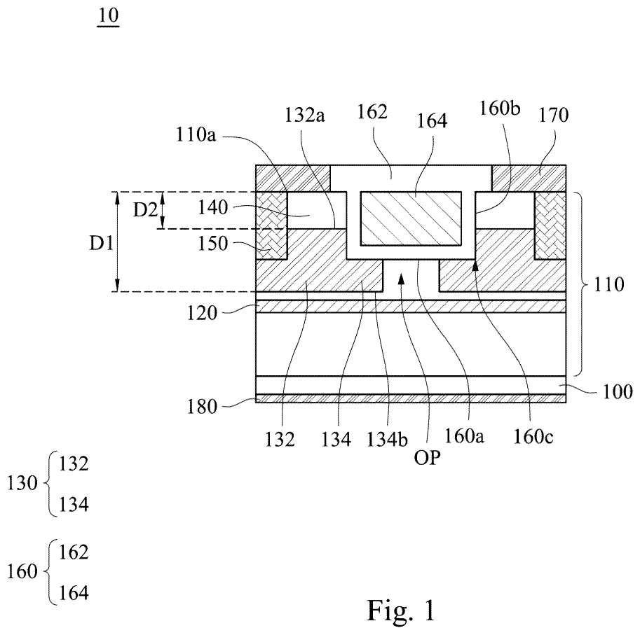

Reference is made to FIG. 1. FIG. 1 is a partial cross-sectional view of a semiconductor device 10 according to some embodiments of the present disclosure. As shown in FIG. 1, the semiconductor device 10 includes a substrate 100, an epitaxial layer 110, a current spreading layer 120, a well 130, a source region 140, a heavily doped region 150, a gate structure 160, a source electrode 170, and a drain electrode 180.

As shown in FIG. 1, the epitaxial layer 110 is disposed on the substrate 100. The current spreading layer 120 is disposed in the epitaxial layer 110. The well 130 has a first portion 132 and a second portion 134 disposed in the epitaxial layer 110 and above the current spreading layer 120. The source region 140 and the heavily doped region 150 are disposed in the epitaxial layer 110 and on the well 130. The gate structure 160 includes a gate oxide layer 162 and a gate electrode 164 disposed in the epitaxial layer 110 and on the well 130. The source region 140 is also between the gate structure 160 and the heavily doped region 150.

In some embodiments, the source electrode 170 is formed on a top surface 110a of the epitaxial layer 110 and above the heavily doped region 150. In other words, the heavily doped region 150 is disposed between the well 130 and the source electrode 170. The source electrode 170 is electrically connected to the well 130. The drain electrode 180 is formed below the substrate 100. The source electrode 170 and the drain electrode 180 include conductive metal.

In some embodiments, the substrate 100, the epitaxial layer 110, the current spreading layer 120, and the source region 140 have a first conductive type. For example, the substrate 100, the epitaxial layer 110, the current spreading layer 120, and the source region 140 include n-type semiconductor layers. In some embodiments, a doping concentration of the source region 140 is greater than a doping concentration of the epitaxial layer 110. For example, a doping concentration of the substrate 100 is between 10¹⁴ #/cm³ and 10¹⁷ #/cm³. The doping concentration of the epitaxial layer 110 is between 10¹⁷ #/cm³ and 10²⁰ #/cm³. The doping concentration of the source region 140 is between 10¹⁸ #/cm³ and 10²¹ #/cm³. The epitaxial layer 110 may be formed as a drift region of the semiconductor device 10.

In some embodiments, the well 130 and the heavily doped region 150 have a second conductive type different from the first conductive type. For example, the well 130 and the heavily doped region 150 include p-type semiconductor layers. In some embodiments, a doping concentration of the heavily doped region 150 is greater than a doping concentration of the well 130. The well 130 may also be referred to as a lightly doped region. For example, the doping concentration of the well 130 is between 10¹⁷ #/cm³ and 10²⁰ #/cm³. The doping concentration of the heavily doped region 150 is between 10¹⁸ #/cm³ and 10²¹ #/cm³.

As aforementioned, the gate structure 160 includes the gate oxide layer 162 and the gate electrode 164. In some embodiments, the gate oxide layer 162 may include, for example, silicon dioxide (SiO₂). The gate electrode 164 may include a polysilicon gate or a conductive metal.

To improve the reliability of the semiconductor device, in some embodiments of the present disclosure, a doping depth of the well 130 (i.e., a depth of a bottom surface 134b of the second portion 134) is increased to prevent the electric field from accumulating around corner points of the gate structure 160, thereby increasing the breakdown voltage and reducing the on-state resistance.

Therefore, as shown in FIG. 1, the well 130 extends from a sidewall 160b of the gate structure 160 to a bottom surface 160a of the gate structure 160. In other words, in some embodiments, a junction 160c between the sidewall 160b and the bottom surface 160a of the gate structure 160 is completely covered by the well 130.

In particular, as shown in FIG. 1, the first portion 132 of the well 130 surrounds the sidewall 160b of the gate structure 160 and is in contact with the sidewall 160b. The second portion 134 is disposed below the gate structure 160 and the top surface of the second portion 134 is in contact with the bottom surface 160a of the gate structure 160. In some embodiments, the doping concentration of first portion 132 is substantially equal to the doping concentration of second portion 134.

In some embodiments, a depth D1 of the bottom surface 134b of the second portion 134 relative to the top surface 110a of the epitaxial layer 110 is greater than about 1 micron to ensure that the well 130 completely covers the junction 160c. In addition, in some embodiments, a depth of the top surface of the second portion 134, which is equivalent to a depth of the bottom surface 160a of the gate structure 160 shown in FIG. 1, is greater than a depth D2 of a top surface 132a of the first portion 132.

In some embodiments, as shown in FIG. 1, the second portion 134 has an opening OP. The epitaxial layer 110 may be in contact with the bottom surface 160a of the gate structure 160 through the opening OP.

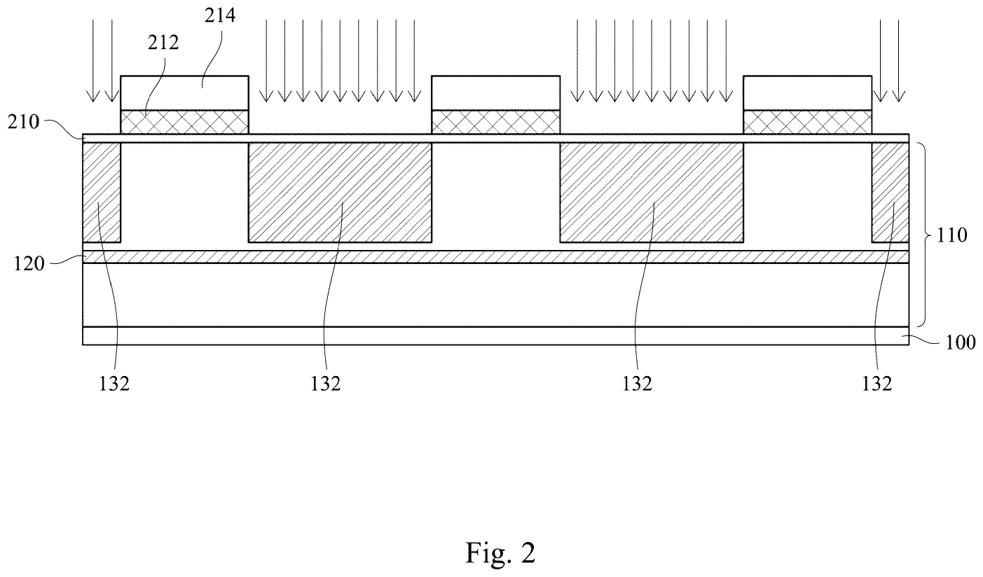

Reference is made to FIG. 2 to FIG. 5. FIG. 2 to FIG. 5 are partial cross-sectional views of intermediate stages of a method for forming the semiconductor device 10 according to some embodiments of the present disclosure. It should be noted that the partial cross-sectional views of the intermediate stages of the method illustrates a plurality of semiconductor device 10 that are periodically arranged and connected.

First, as shown in FIG. 2, the epitaxial layer 110 is formed on the substrate 100. Then, a first ion implantation process is performed to form the current spreading layer 120 in the epitaxial layer 110. The current spreading layer 120 is configured to reduce the on-state resistance of the semiconductor device 10. In some embodiments, the substrate 100, the epitaxial layer 110, and the current spreading layer 120 have the first conductive type. For example, the substrate 100, the epitaxial layer 110, and the current spreading layer 120 include n-type semiconductor layers. In some embodiments, the doping concentration of the substrate 100 is between 10¹⁴ #/cm³ and 10¹⁷ #/cm³. The doping concentration of the epitaxial layer 110 is between 10¹⁷ #/cm³ and 10²⁰ #/cm³. The doping concentration of the current spreading layer 120 is between 10¹⁶ #/cm³ and 10¹⁹ #/cm³.

Next, as shown in FIG. 2, a second ion implantation process is performed using a mask 210, a mask 212, and a mask 214 as masks for ion implantation to form the first portion 132 of the well in the epitaxial layer 110. The well has the second conductive type different from the first conductive type. For example, the well includes a p-type semiconductor layer. In some embodiments, the mask 210, the mask 212, and the mask 214 include the same material. In some other embodiments, the mask 210 and the mask 214 include the same material, such as silicon oxide (SiO₂), and the mask 212 includes a different material than the mask 210 and the mask 214, such as polycrystalline silicon (polysilicon).

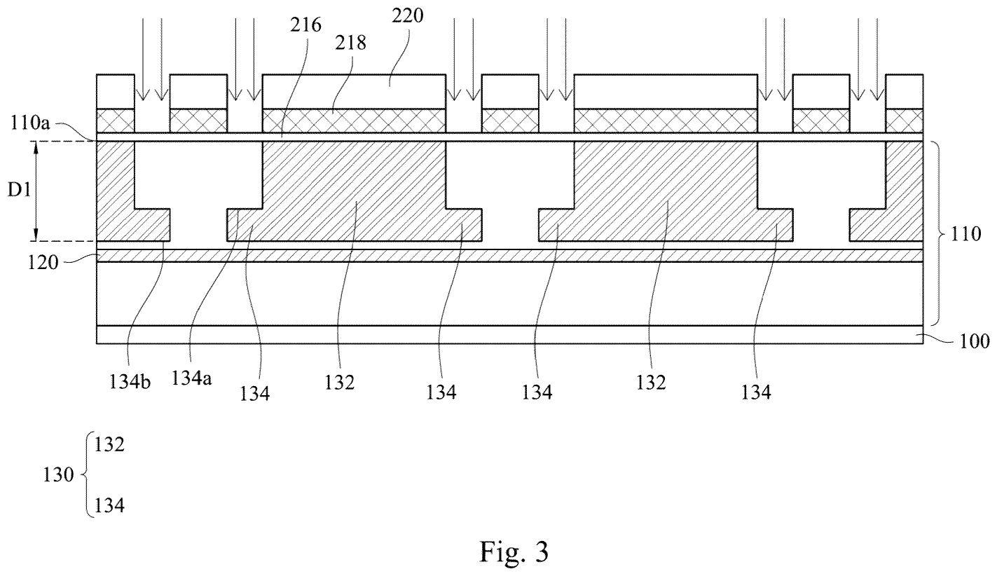

Next, as shown in FIG. 3, a third ion implantation process is performed using a mask 216, a mask 218, and a mask 220 to form the second portion 134 of the well in the epitaxial layer 110. The second portion 134 is adjacent to the first portion 132. The doping concentration of the first portion 132 is substantially equal to the doping concentration of the second portion 134. The first portion 132 and the second portion 134 are collectively referred to as the well 130. As aforementioned, in some embodiments, a distance between the bottom surface 134b of the second portion 134 and the top surface 110a of the epitaxial layer 110 is greater than about 1 micron. In other words, the depth D1 of the bottom surface 134b is greater than about 1 micron.

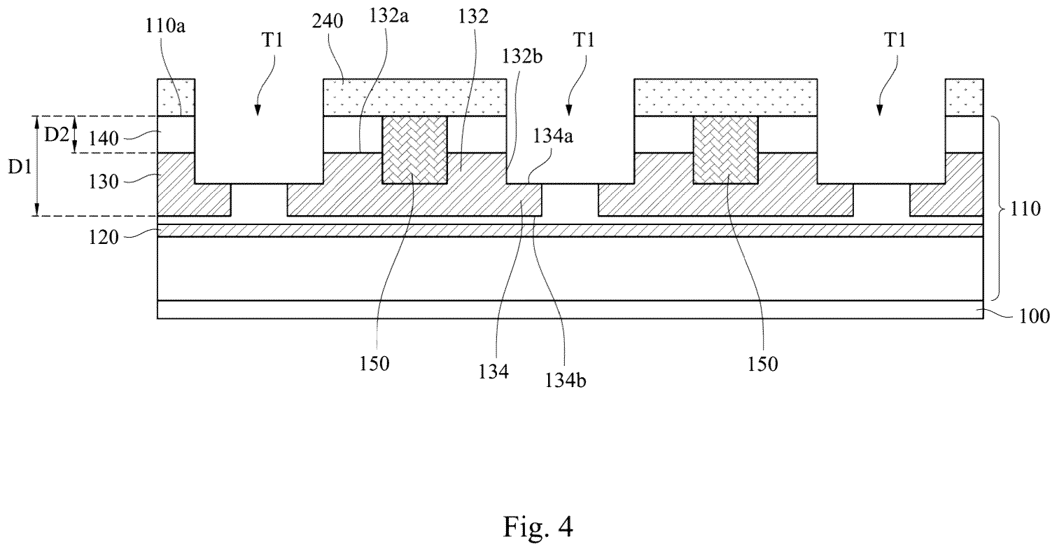

Reference is made to FIG. 4. As shown in FIG. 4, after the third ion implantation process, a fourth ion implantation process is then performed to form a source region 140 having the first conductive type (e.g., n-type) in the epitaxial layer 110 and adjacent to the first portion 132 of the well. In some embodiments, the source region 140 is formed such that the top surface 132a of the first portion 132 of the well is as shown in FIG. 4. In some embodiments, the depth D2 of the top surface 132a of the first portion 132 is less than the depth D1 of the bottom surface 134b of the second portion 134.

Then, a fifth ion implantation process is performed to form a heavily doped region 150 in the epitaxial layer 110 and on the well 130. The heavily doped region 150 has the second conductive type (e.g., p-type). In some embodiments, the doping concentration of the heavily doped region 150 is greater than the doping concentration of the well 130. For example, the doping concentration of the well 130 is between 10¹⁷ #/cm³ and 10²⁰ #/cm³. The doping concentration of the heavily doped region 150 is between 10¹⁸ #/cm³ and 10²¹ #/cm³. In some embodiments, the depth of a bottom surface of the heavily doped region 150 is between the depth D1 and the depth D2.

Next, a portion of the epitaxial layer 110 is removed to form a trench T1 to expose a top surface 134a of the second portion 134 of the well 130. For example, as shown in FIG. 4, the trench T1 is etched using a hard mask 240. In some embodiments, the trench T1 further exposes a sidewall 132b of the first portion 132 of the well 130. In some embodiments, the hard mask 240 includes silicon dioxide.

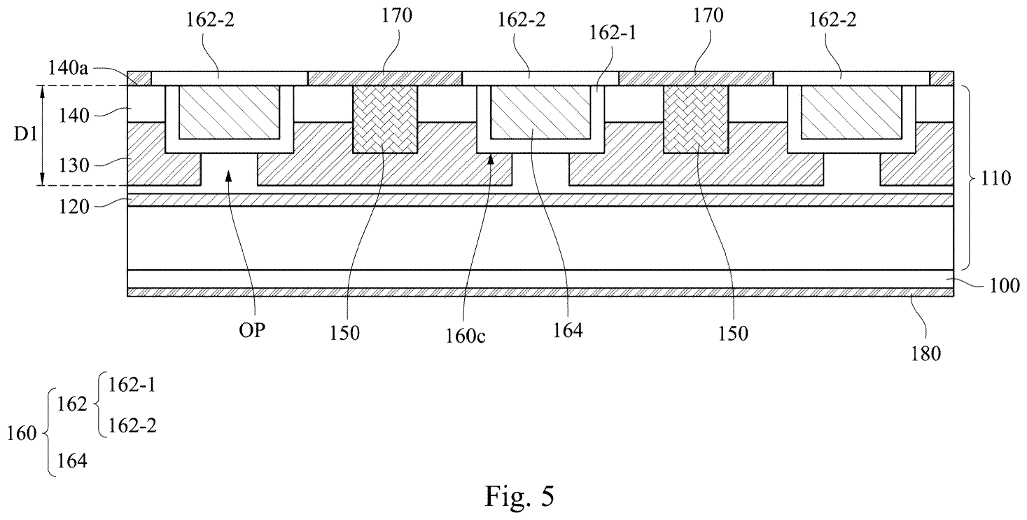

Reference is made to FIG. 5. Next, a gate structure is formed in the trench T1. As aforementioned, in some embodiments, the gate structure includes a gate oxide layer and a gate electrode. In some embodiments, the gate oxide layer is formed in two stages.

For example, in some embodiments, the first gate oxide layer 162-1 is conformally deposited in the trench T1 and on the top surfaces of the source region 140 and the heavily doped region 150.

Next, the gate electrode 164 is deposited to further fill the trench T1 and completely cover the first gate oxide layer 162-1.

Then, the formed gate electrode 164 is subjected to a planarization process, such as chemical mechanical polishing/planarization (CMP), to remove a portion of the gate electrode 164 that is higher than the source region 140 to expose the top surface of the source region 140 and make the first gate oxide layer 162-1 and the gate electrode 164 substantially level with the top surface of the source region 140.

Next, a second gate oxide layer 162-2 is deposited to cover the source region 140, the first gate oxide layer 162-1, and the gate electrode 164. As such, the gate electrode 164 is covered by the first gate oxide layer 162-1 and the second gate oxide layer 162-2. The first gate oxide layer 162-1 and the second gate oxide layer 162-2 are collectively referred to as the gate oxide layer 162. The gate oxide layer 162 and the gate electrode 164 are collectively referred to as the gate structure 160.

Since the trench T1 (as shown in FIG. 4) exposes the top surface 134a of the second portion 134 of the well 130 and the sidewall 132b of the first portion 132, the gate structure 160 formed in the trench T1 is in contact with the top surface 134a and the sidewall 132b. In other words, the junction 160c between the bottom surface 160a and the sidewall 160b of the gate structure 160 is completely covered by the well 130. In this way, the electric field accumulation around the junction 160c may be prevented, thereby increasing the breakdown voltage of the resultant semiconductor device. In some embodiments, the second portion 134 has an opening OP. The epitaxial layer 110 is in contact with the gate structure 160 through the opening OP.

Next, a portion of the second gate oxide layer 162-2 is removed to expose the source region 140 and the heavily doped region 150 and separate the neighboring gate structures 160 from each other.

Finally, the source electrode 170 is formed on the source region 140 and the heavily doped region 150. The source electrode 170 is electrically connected to the well 130. At the same time, the drain electrode 180 is formed below the substrate 100. The resultant semiconductor device is a vertical MOSFET with a trench gate structure, as shown with the semiconductor device 10 in FIG. 1.

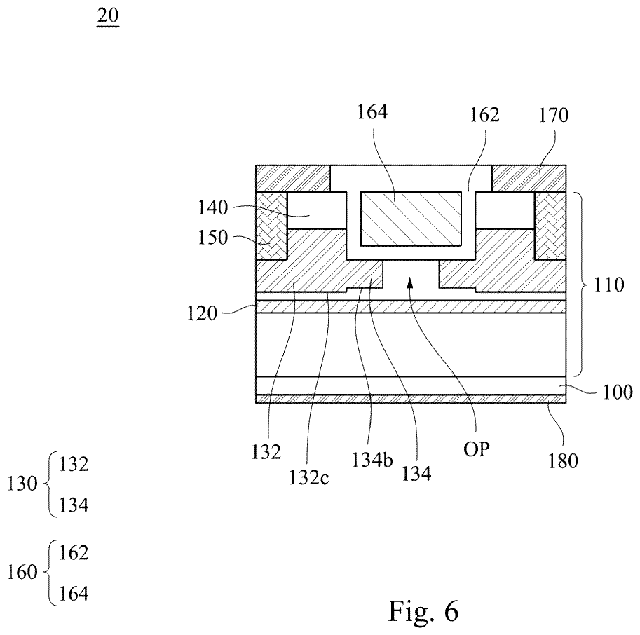

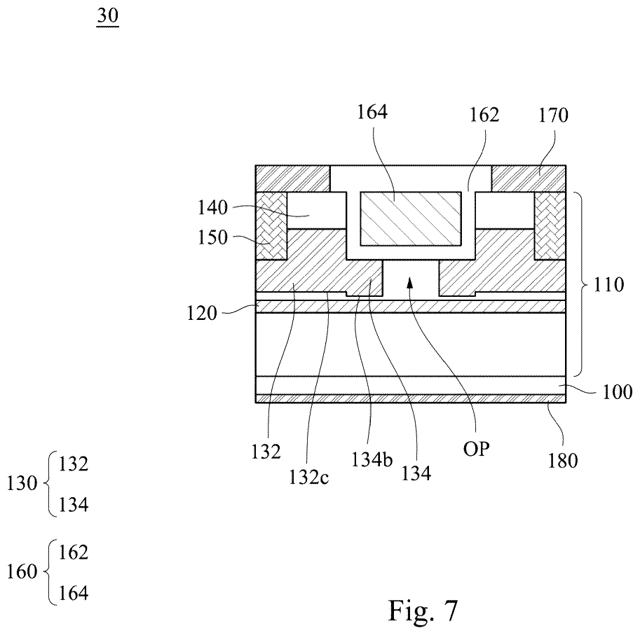

Reference is made to FIG. 6 and FIG. 7. FIG. 6 and FIG. 7 are partial cross-sectional views of the semiconductor device 20 and the semiconductor device 30 according to some other embodiments of the present disclosure, respectively. As shown in FIG. 6, the difference between the semiconductor device 20 and the semiconductor device 10 lies in that the depth of the bottom surface 134b of the second portion 134 of the semiconductor device 20 is less than the depth of a bottom surface 132c of the first portion 132. On the other hand, as shown in FIG. 7, the difference between the semiconductor device 30 and the semiconductor device 10 lies in that the depth of the bottom surface 134b of the second portion 134 of the semiconductor device 30 is greater than the depth of the bottom surface 132c of the first portion 132.

According to the foregoing recitations of the embodiments of the disclosure, it may be seen that in the semiconductor device and the method for forming the semiconductor device of some embodiments of the present disclosure, by increasing the depth of the well (i.e., the maximum depth of the lightly doped region) so that the well covers the corner points of the gate structure, the electric field accumulation around the corner points may be reduced. To be more specific, by performing two ion implantation processes, the first portion and the second portion of the well are formed. The first portion surrounds the sidewall of the gate structure, and the second portion extends to the bottom surface of the gate structure. As such, the junction between the sidewall and the bottom surface of the gate structure is covered by the first portion and the second portion of the well. Therefore, the breakdown voltage of the semiconductor device can be improved and its on-state resistance can be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A semiconductor device, comprising:
an epitaxial layer having a first conductive type;
a gate structure disposed in the epitaxial layer;
a well disposed in the epitaxial layer and having a second conductive type different from the first conductive type, wherein the well extends from a sidewall of the gate structure to a bottom surface of the gate structure; and
a source electrode disposed above the epitaxial layer and electrically connected to the well.

2. The semiconductor device according to claim 1, wherein a junction between the sidewall and the bottom surface of the gate structure is completely covered by the well.

3. The semiconductor device according to claim 1, wherein a depth of a bottom surface of the well is greater than about 1 micron.

4. The semiconductor device according to claim 1, wherein the well has a first portion and a second portion, wherein the first portion surrounds the sidewall of the gate structure and is in contact with the sidewall, and the second portion is disposed below the gate structure and is in contact with the bottom surface of the gate structure.

5. The semiconductor device according to claim 4, wherein the second portion has an opening and the epitaxial layer is in contact with the bottom surface of the gate structure through the opening.

6. The semiconductor device according to claim 4, wherein a depth of a top surface of the first portion is less than a depth of a top surface of the second portion.

7. The semiconductor device according to claim 4, wherein a doping concentration of the first portion is substantially equal to a doping concentration of the second portion.

8. The semiconductor device according to claim 1, further comprising a heavily doped region, wherein the heavily doped region is disposed between the well and the source electrode, the heavily doped region has the second conductive type, and the heavily doped region has a doping concentration greater than a doping concentration of the well.

9. The semiconductor device according to claim 8, further comprising a source region having the first conductive type and disposed between the gate structure and the heavily doped region.

10. A method for forming a semiconductor device, comprising:
forming an epitaxial layer on a substrate, wherein the epitaxial layer has a first conductive type;
performing a first implantation process to form a first portion of a well in the epitaxial layer, wherein the first portion of the well has a second conductive type different from the first conductive type;
performing a second implantation process to form a second portion of the well in the epitaxial layer and adjacent to the first portion, wherein the second portion of the well has the second conductive type;
performing a third implantation process to form a heavily doped region in the epitaxial layer and adjacent to the well, wherein the heavily doped region has the second conductive type;
removing a portion of the epitaxial layer to form a trench that exposes a top surface of the second portion of the well; and
forming a gate structure in the trench.

11. The method according to claim 10, wherein the trench further exposes a sidewall of the first portion of the well.

12. The method according to claim 10, wherein a distance between a bottom surface of the second portion of the well and a top surface of the epitaxial layer is greater than about 1 micron.

13. The method according to claim 10, further comprising performing a fourth implantation process to form a source region between the gate structure and the heavily doped region, wherein the source region has the first conductive type.

14. The method according to claim 10, wherein a depth of a top surface of the first portion is less than a depth of the top surface of the second portion.

15. The method according to claim 10, wherein a doping concentration of the first portion is substantially equal to a doping concentration of the second portion.

16. The method according to claim 10, wherein a doping concentration of the heavily doped region is greater than a doping concentration of the well.

17. The method according to claim 10, wherein the gate structure is formed in the trench such that the gate structure is in contact with the top surface of the second portion of the well.

18. The method according to claim 10, wherein the second portion has an opening and the epitaxial layer is in contact with the gate structure through the opening.

19. The method according to claim 10, wherein the gate structure is formed in the trench such that a junction between a sidewall and a bottom surface of the gate structure is completely covered by the well.
